(19) United States
(12) Patent Application Publication
(10) Pub. No.: US 2016/0060474 A1
(43) Pub. Date: Mar. 3, 2016

(54) NANOPARTICLE INK COMPOSITIONS, PROCESS AND APPLICATIONS

(71) Applicants: Henkel IP & Holding GmbH, Duesseldorf (DE); Henkel AG & Co. KGaA, Duesseldorf (DE)

(72) Inventors: Rudolf W. Oldenzijl, Hoogezand (NL); Gunther Dreezen, Balen - Olmen (BE); Jianping Chen, Irvine, CA (US)

(21) Appl. No.: 14/935,500

(22) Filed: Nov. 9, 2015

Related U.S. Application Data
(63) Continuation of application No. PCT/US2014/044990, filed on Jul. 1, 2014.
(60) Provisional application No. 61/841,634, filed on Jul. 1, 2013.

(51) Int. Cl. C09D 11/52; H05K 1/09; C08K 5/05; C09D 163/00; C08K 5/053; H05K 3/00; G06F 3/041

(52) U.S. Cl. CPC C09D 11/52; H05K 3/007; H05K 1/09; G06F 3/0412; C09D 163/00; C08K 5/053; C08K 5/05; G06F 2203/04103

(57) ABSTRACT

Provided herein are conductive ink compositions having a good balance between adhesion to substrate, nanoparticle stability, the ability to be sintered at relatively low temperatures, and good electrical conductivity. In one aspect, there are provided conductive networks prepared from compositions according to the present invention. In certain aspects, such conductive networks are suitable for use in touch panel displays. In certain aspects, the invention relates to methods for adhering nanoparticulate silver to a non-metallic substrate. In certain aspects, the invention relates to methods for improving the adhesion of nanoparticulate silver-filled formulation to a non-metallic substrate.

### FIELD OF THE INVENTION

The present invention relates to silver-containing conductive ink formulations, and various uses thereof. In one aspect, the invention relates to compositions containing stabilized silver nanoparticles. In another aspect, the invention relates to conductive networks and methods for preparing same. In yet another aspect, the invention relates to methods for adhering silver nanoparticles to a non-metallic substrate.

### SUMMARY OF THE INVENTION

In accordance with the present invention, there are provided conductive ink compositions having a good balance between adhesion to substrate, nanoparticle stability, the ability to be sintered at relatively low temperatures, and good electrical conductivity. In one aspect, there are provided conductive networks prepared from compositions according to the present invention. In certain aspects, such conductive networks are suitable for use in touch panel displays. In certain aspects, the invention relates to methods for adhering nanoparticulate silver to a non-metallic substrate. In certain aspects, the invention relates to methods for improving the adhesion of nanoparticulate silver-filled thermoset resin to a non-metalic substrate.

### DETAILED DESCRIPTION OF THE INVENTION

In accordance with the present invention, there are provided compositions comprising:

stabilized silver nanoparticles, an acidic component, a thermoset resin, and an hydroxy-containing diluent.

Stabilized silver particles typically comprise at least about 20 weight percent of the composition, up to about 95 weight percent thereof. In some embodiments, stabilized silver particles comprise about 30 up to about 90 weight percent of compositions according to the present invention; in some embodiments, stabilized silver particles comprise in the range of about 50 up to about 80 weight percent of compositions according to the present invention.

Stabilized silver nanoparticles contemplated for use in the practice of the present invention typically have a particle size in the range of about 5 up to about 200 nanometers. In certain embodiments, silver nanoparticles contemplated for use herein have a particle size of at least 30 nanometers. In other embodiments of the present invention, silver nanoparticles contemplated for use herein have a particle size of at least 80 nanometers. In certain embodiments, silver nanoparticles contemplated for use herein have a particle size of at least 110 nanometers. Thus, in some embodiments, silver nanoparticles having a particle size in the range of about 30-200 nm are contemplated for use herein; in some embodiments, silver nanoparticles having a particle size in the range of about 80-200 nm are contemplated for use herein; in some embodiments, silver nanoparticles having a particle size in the range of about 110-200 nm are contemplated for use herein; in some embodiments, silver nanoparticles having a particle size in the range of about 30-150 nm are contemplated for use herein; in some embodiments, silver nanoparticles having a particle size in the range of about 80-150 nm are contemplated for use herein; in some embodiments, silver nanoparticles having a particle size in the range of about 110-180 nm are contemplated for use herein.

Silver nanoparticles contemplated for use in the practice of the present invention are typically stabilized. As readily recognized by those of skill in the art, silver nanoparticles can be stabilized in a variety of ways, e.g., by the presence of one or more capping agents (which are used to stabilize nanoparticles from aggregation). Exemplary capping agents include polyvinyl alcohol, poly(N-vinyl-2-pyrrolidone), gum arabic, α-methacrylic acid, 11-mercaptoundecanoic acid or the disulfide derivative thereof, citric acid, trisodium citrate, stearic acid, palmitic acid, octanoic acid, decanoic acid, polyethylene glycol and derivatives thereof, polyacrylic acid and aminomodified polyacrylic acid, 2-mercaptoethanol, starch, and the like, as well as mixtures of any two or more thereof.

As readily recognized by those of skill in the art, even small amounts of capping agent are effective to stabilize silver nanoparticles. Typically, the amount of capping agent falls in the range of about 0.05 up to about 5 weight percent of the composition. In some embodiments, the amount of capping agent employed falls in the range of about 0.1 up to about 2.5 weight percent of the composition.

A wide variety of acidic components are contemplated for use herein, so long as such components are miscible with the other components of compositions according to the present invention. Such acidic materials are weak-to-mild acids, typically having a pH<7. In certain embodiments, acidic components contemplated for use herein have a pH in the range of at least 1, but less than 7. In certain embodiments, acidic components contemplated for use herein have a pH in the range of at least 2 up to about 6. Exemplary acidic components contemplated for use herein include phosphoric acid, vinylphosphoric acid, polyphosphoric acid, formic acid, acetic acid, chloroacetic acid, trifluoroacetic acid, oxalic acid, oleic acid, benzoic acid, p-toluenesulfonic acid, and the like, as well as mixtures of any two or more thereof.

Suitable quantities of the acidic component typically fall in the range of about 0.1 up to about 5 weight percent of the composition. In certain embodiments, the amount of acidic component employed will fall within the range of about 0.5 up to 2 weight percent.

A wide variety of thermoset resins are contemplated for use herein, e.g., epoxy-functionalized resins, acrylates, cyanate esters, silicones, oxetanes, maleimides, and the like, as well as mixtures of any two or more thereof.

A wide variety of epoxy-functionalized resins are contemplated for use herein, e.g., liquid-type epoxy resins based on bisphenol A, solid-type epoxy resins based on bisphenol A, liquid-type epoxy resins based on bisphenol F (e.g., Epiclon EXA-835LV), multifunctional epoxy resins based on phenol-novolac resin, dicyclopentadiene-type epoxy resins (e.g., Epiclon HP-7200L), naphthalene-type epoxy resins, and the like, as well as mixtures of any two or more thereof.

Exemplary epoxy-functionalized resins contemplated for use herein include the diepoxide of the cycloaliphatic alcohol, hydrogenated bisphenol A (commercially available as Epalloy 5000), a difunctional cycloaliphatic glycidyl ester of hexahydrophthallic anhydride (commercially available as Epalloy 5200), Epiclon EXA-835LV, Epiclon HP-7200L, and the like, as well as mixtures of any two or more thereof.

Acrylates contemplated for use in the practice of the present invention are well known in the art. See, for example, U.S. Pat. No. 5,717,034, the entire contents of which are hereby incorporated by reference herein.

Cyanate esters contemplated for use in the practice of the present invention are well known in the art. See, for example, U.S. Pat. No. 5,718,941, the entire contents of which are hereby incorporated by reference herein.

Silicones contemplated for use in the practice of the present invention are well known in the art. See, for example, U.S. Pat. No. 5,717,034, the entire contents of which are hereby incorporated by reference herein.

Oxetanes (i.e., 1,3-propylene oxides) are heterocyclic organic compounds with the molecular formula C₃H₆O, having a four-membered ring with three carbon atoms and one oxygen atom. The term oxetane also refers generally to any organic compound containing an oxetane ring. See, for example, Burkhard et al., in Angew. Chem. Int. Ed. 2010, 49, 9052-9067, the entire contents of which are hereby incorporated by reference herein.

Maleimides contemplated for use in the practice of the present invention are well known in the art. See, for example, U.S. Pat. No. 5,717,034, the entire contents of which are hereby incorporated by reference herein.

Only small amounts of thermoset resin is required to obtain the benefits thereof. Typically thermoset resins comprise only about 0.1 up to about 5 weight percent of the composition. In some embodiments, thermoset resins comprise about 0.2 up to about 3 weight percent of the total composition.

Hydroxy-containing diluents contemplated for use herein include water and hydroxy-containing compounds having a C₁ up to about a C₁₀ backbone. Exemplary hydroxy-containing diluents include water, methanol, ethanol, propanol, ethylene glycol, propylene glycol, glycerol, terpineol, and the like, as well as mixtures of any two or more thereof.

The amount of hydroxy-containing diluent contemplated for use in accordance with the present invention can vary widely, typically falling in the range of about 5 up to about 80 weight percent of the composition. In certain embodiments, the amount of hydroxy-containing diluent falls in the range of about 10 up to 60 weight percent of the total composition. In some embodiments, the amount of hydroxy-containing diluent falls in the range of about 20 up to about 50 weight percent of the total composition.

Optionally, compositions described herein may include flow additives, and the like. Flow additives contemplated for optional use herein include silicon polymers, ethyl acrylate/2-ethylhexyl acrylate copolymers, alkylol ammonium salt of phosphoric acid esters of ketoxime, and the like, as well as combinations of any two or more thereof.

In accordance with another embodiment of the present invention, there are provided methods of preparing conductive networks, said method comprising:
applying a composition as described herein to a suitable substrate, and thereafter sintering said composition.

A wide variety of substrates are contemplated for use herein, so long as they are non-conductive. Exemplary substrates include a polyethylene terephthalate, a polymethyl methacrylate, a polyethylene, a polypropylene, a polycarbonate, an epoxy resin, a polyimide, a polyamide, a polyester, glass, or the like.

A particular advantage of compositions according to the present invention is that they can be sintered at relatively low temperatures, e.g., in some embodiments at temperatures no greater than about 150° C. When sintered at such temperatures, it is contemplated that the composition be exposed to sintering conditions for a time in the range of 0.5 up to about 30 minutes.

In certain embodiments, it is contemplated that sintering may be carried out at a temperature no greater than about 120° C. When sintered at such temperatures, it is contemplated that the composition be exposed to sintering conditions for a time in the range of 0.1 up to about 2 hours.

In accordance with yet another embodiment of the present invention, there are provided conductive networks comprising a sintered array of nanoparticulate silver particles having a resistivity of no greater than 1×10⁻⁴ Ohms.cm.

Such conductive networks are typically applied to a substrate, and display substantial adhesion thereto. Adhesion between the conductive network and the substrate can be determined in a variety of ways, e.g., by ASTM standard cross-cut tape test pursuant to test method D 3359-97. In accordance with the present invention, adhesion comparable to at least ASTM level 1B is observed (i.e., at least 35% of the originally adhered film surface remains attached to the substrate after being subjected to the tape test). In certain embodiments of the present invention, adhesion comparable to at least ASTM level 2B is observed (i.e., at least 65% of the originally adhered film surface remains attached to the substrate after being subjected to the tape test). In certain embodiments of the present invention, adhesion comparable to at least ASTM level 3B is observed (i.e., at least 85% of the originally adhered film surface remains attached to the substrate after being subjected to the tape test). In certain embodiments of the present invention, adhesion comparable to at least ASTM level 4B is observed (i.e., at least 95% of the originally adhered film surface remains attached to the substrate after being subjected to the tape test). In certain embodiments of the present invention, adhesion comparable to at least ASTM level 5B is observed (i.e., 100% of the originally adhered film surface remains attached to the substrate after being subjected to the tape test).

In accordance with still another embodiment of the present invention, there are provided methods for adhering silver particles having a particle size in the range of about 5 up to about 200 nanometers to a non-metallic substrate, said method comprising:
applying a composition as described herein to said substrate, and thereafter sintering said composition.

In accordance with this embodiment of the present invention, sintering under low temperature (e.g., at a temperature no greater than about 150° C.; or at a temperature no greater than about 120° C.) is contemplated.

In accordance with a further embodiment of the present invention, there are provided methods for improving the adhesion of nanoparticulate silver-filled thermoset resin to a non-metallic substrate, said method comprising including:
an acidic component, and
an hydroxy-containing diluent
   in said silver-filled thermoset resin.
   Nanoparticulate silver, thermoset resins, acidic components, and hydroxy-containing diluents as described herein are contemplated for use in this embodiment of the present invention.

In accordance with yet another embodiment of the present invention, there are provided touch panel displays comprising a transparent substrate having an electrically conductive layer thereon, wherein said electrically conductive layer comprises a cured layer of a composition according to the invention.

Various aspects of the present invention are illustrated by the following non-limiting examples. The examples are for illustrative purposes and are not a limitation on any practice of the present invention. It will be understood that variations and modifications can be made without departing from the spirit and scope of the invention. One of ordinary skill in the art readily knows how to synthesize or commercially obtain the reagents and components described herein.

### Example 1

Ink was made by mixing nanoparticulate silver with the desired amount of diluent and optionally H₃PO₄ (added to the “modified” ink). Mixing was carried out in a Speedmixer until the composition was substantially homogeneous. Material was applied to a substrate and a film prepared with a 10 micron wire bar. The material was then dried at 150° C. for 10 minutes in a box oven. A 0.5 by 5 cm piece was cut, and the thickness and resistance thereof was measured, and the resistance calculated based thereon. Results are presented in Table 1.

TABLE 1

| | Surface | | | Volume |
|---|---|---|---|---|
| | resistance | Thickness | | resistivity |
| Ink | (Ohm/sq) | (Micron) | Ohm/sq/25 μm | (Ohm · cm) |
| Standard Ink | 0.13 | 5 | 0.026 | 6.5E−05 |
| Modified ink | 0.026 | 3 | 0.0031 | 7.80E−06 |

The results set forth in Table 1 demonstrate that the mere addition of 2.0 wt % phosphoric acid to a nanoparticulate silver, epoxy-containing formulation reduces the thickness to which the formulation can be applied, and significantly reduces the resistivity thereof.

### Example 2

Additional inks were prepared and evaluated, as summarized in Table 2.

TABLE 2

| | Sample no. | | | | | |
|---|---|---|---|---|---|---|
| Component | 1 | 2 | 3 | 4 | 5 | 6 |
| Ag, g. | 20 | 20 | 20 | 20 | 20 | 20 |
| H₃PO₄ | 0 | 0.4 | 0.1 | 0.2 | 0.3 | 0.4 |
| Epalloy 5000 | 0.05 | 0 | 0.05 | 0.05 | 0.05 | 0.05 |
| Epalloy 5200 | 0.0125 | 0 | 0.0125 | 0.0125 | 0.0125 | 0.0125 |
| Track | | | | | | |
| resistance | | | | | | |
| 5 min @ | ∞ | 0.044 | 0.776 | 0.077 | 0.047 | 0.027 |
| 150 C. | | | | | | |
| 10 min @ | 5.51 | 0.079 | 0.813 | 0.096 | 0.056 | 0.079 |
| 150 C. | | | | | | |
| 15 min @ | 0.5 | 0.043 | 0.346 | 0.013 | 0.012 | 0.063 |
| 150 C. | | | | | | |
| Vr (Ohm · cm) | | | | | | |
| 5 min @ | ∞ | 7.09E−0.6 | 1.92E−0.4 | 1.08E−0.5 | 1.51E−0.5 | 9.62E−0.6 |
| 150 C. | | | | | | |
| 10 min @ | 6.40E−0.4 | 9.70E−0.6 | 1.05E−0.4 | 1.15E−0.5 | 1.43E−0.5 | 1.45E−0.5 |
| 150 C. | | | | | | |
| 15 min @ | 2.04E−0.4 | 6.33E−0.6 | 3.13E−0.5 | 1.46E−0.5 | 8.82E−0.6 | 1.06E−0.5 |
| 150 C. | | | | | | |
| Adhesion | | | | | | |
| 5 min @ | ++ | −− | ++ | ++/− | − | −− |
| 150 C. | | | | | | |
| 10 min @ | ++ | −− | ++ | ++/− | − | − |
| 150 C. | | | | | | |
| 15 min @ | ++ | −− | ++ | ++/− | − | −− |
| 150 C. | | | | | | |

In the presence of phosphoric acid, Sample no. 2 has better conductivity than Sample no. 1 under the same curing conditions. Moreover, upon addition of epoxy materials (i.e., a combination of Epalloy 5000 and 5200), Sample nos. 3 and 4 have improved adhesion to the PET substrate relative to Sample no. 2. Overall, Sample no. 4 is observed to have the most desirable balance of conductivity and adhesion, relative to Sample nos. 1, 2, 3 and 6.

### Example 3

Additional inks were prepared and evaluated, as summarized in Table 3.

TABLE 3

| | Sample no. | | | | |
|---|---|---|---|---|---|
| | 7 | 8 | 9 | 10 | 11 |
| Component | | | | | |
| Ag, g. | 40 | 40 | 40 | 40 | 40 |
| H₃PO₄ | 0.8 | 0.8 | 0.4 | 0.8 | 0.4 |
| Ethylene | 5 | 5 | 5 | − | − |
| glycol | | | | | |
| Terpineol | − | − | − | 5 | 5 |
| Epalloy 5000 | 0.1 | 0.1 | 0.1 | 0.1 | 0.1 |
| Epalloy 5200 | 0.025 | 0.025 | 0.025 | 0.025 | 0.025 |
| N-ethyl-2- | 2 | 2 | 2 | 2 | 2 |
| pyrrolidone | | | | | |
| Track | | | | | |
| resistance | | | | | |
| 5 min | | 0.109 | 0.21 | 0.153 | 0.202 |
| @150 C. | | | | | |
| 10 min | | 0.108 | 0.153 | 0.266 | 0.204 |
| @150 C. | | | | | |
| 15 min | | 0.104 | 0.179 | 0.169 | 0.117 |
| @150 C. | | | | | |
| Vr | | | | | |
| (Ohm · cm) | | | | | |
| 5 min | 1.50E−06 | 5.76E−06 | 1.23E−05 | 5.76E−06 | 2.15E−05 |
| @150 C. | | | | | |
| 10 min | | 5.43E−06 | 7.67E−06 | 2.01E−05 | 1.82E−05 |
| @150 C. | | | | | |
| 15 min | | 6.54E−06 | 6.73E−06 | 1.26E−05 | 1.39E−05 |
| @150 C. | | | | | |
| Adhesion | | | | | |
| 5 min | ++ | −− | ++ | −− | ++ |
| @150 C. | | | | | |
| 10 min | | − | ++ | − | ++ |
| @150 C. | | | | | |
| 15 min | | − | ++ | − | ++ |
| @150 C. | | | | | |

The results set forth in Table 3 demonstrate that low levels of phosphoric acid are effective for improving conductivity and adhesion of nanoparticulate silver-containing formulations. Indeed, in certain circumstances, lower amounts of phosphoric acid (i.e., less than 0.1 wt %) appear to be preferable.

### Example 4

Additional inks were prepared and evaluated, as summarized in Table 4.

TABLE 4

| | Sample no. | | |
|---|---|---|---|
| | 12 | 13 | 14 |
| Component | | | |
| Ag, g. | 40 | 40 | 40 |
| H₃PO₄ | 0.4 | − | − |
| p-toluenesulfonic acid | − | 2.1 | − |
| Oxalic acid | − | − | 1.1 |
| Terpineol | 5 | 5 | 5 |
| Epalloy 5000 | 0.1 | 0.1 | 0.1 |
| Epalloy 5200 | 0.025 | 0.025 | 0.025 |
| N-ethyl-2-pyrrolidone | 2 | 2 | 2 |
| Track resistance | | | |
| 5 min @150 C. | 0.202 | ∞ | 1.51 |
| Vr (Ohm · cm) | | | |
| 5 min @150 C. | 2.15E−05 | − | 1.08E−04 |
| Ohm/sq/25 micron | 0.009 | − | 0.043 |
| Adhesion | | | |
| 5 min @150 C. | ++ | ± | + |

The results summarized in Table 4 demonstrate that the combination of phosphoric acid and certain epoxy resins is highly effective for improving conductivity and adhesion of nanoparticulate silver-containing epoxy formulations.

### Example 5

Additional inks were prepared and evaluated, as summarized in Table 5.

TABLE 5

| | Sample no. | | |
|---|---|---|---|
| | 15 | 16 | 17 |
| Component | | | |
| Ag, g. | 40 | 40 | 40 |
| H₃PO₄ | 0.4 | 0.4 | 0.4 |
| Terpineol | 5 | 5 | 5 |
| Epalloy 5000 | 0.1 | 0.2 | 0.3 |
| Epalloy 5200 | 0.025 | 0.05 | 0.075 |
| N-methyl-2-pyrrolidone | 2 | 2 | 2 |
| Track resistance | | | |
| 5 min @150 C. | 0.202 | 0.63 | 0.47 |
| Vr (Ohm · cm) | | | |
| 5 min @150 C. | 2.15E−05 | 6.59E−05 | 3.84E−05 |
| Ohm/sq/25 micron | 0.009 | 0.026 | 0.015 |
| Adhesion | | | |
| 5 min @150 C. | ++ | ++ | ++ |

The results summarized in Table 5 demonstrate that only small quantities of epoxy are required to achieve improved conductivity and/or adhesion of nanoparticulate silver-containing formulations. Indeed, in some circumstances, it is preferable to limit the amount of epoxy included in invention formulations.

### Example 6

Additional inks were prepared and evaluated, as summarized in Table 6.

TABLE 6

| | Sample no. | | |
|---|---|---|---|
| | 18 | 19 | 20 |
| Component | | | |
| Ag, g. | 40 | 40 | 40 |
| H₃PO₄ | 0.4 | 0.4 | 0.4 |
| Terpineol | 5 | 5 | 5 |
| Phosphoric acid 2-hydroxyethyl | 0.125 | − | − |
| methacrylate ester | | | |
| SR 9054 (UV-2E) | − | 0.125 | − |
| Genorad 40 (UV-3B) | − | − | 0.125 |
| N-methyl-2-pyrrolidone | 2 | 2 | 2 |
| Track resistance | | | |
| 5 min @150 C. | 1.04 | 0.466 | 0.622 |
| Vr (Ohm · cm) | | | |
| 5 min @150 C. | 2.41E−05 | 9.40E−06 | 1.16E−05 |
| Ohm/sq/25 micron | 0.010 | 0.004 | 0.005 |
| Adhesion | | | |
| 5 min @150 C. | ± | −− | −− |

The results summarized in Table 6 demonstrate that a variety of acids can be employed in the practice of the present invention.

Various modifications of the present invention, in addition to those shown and described herein, will be apparent to those skilled in the art of the above description. Such modifications are also intended to fall within the scope of the appended claims.

Patents and publications mentioned in the specification are indicative of the levels of those skilled in the art to which the invention pertains. These patents and publications are incorporated herein by reference to the same extent as if each individual application or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

That which is claimed is:

1. A composition comprising:
stabilized silver nanoparticles,
an acidic component,
a thermoset resin, and
an hydroxy-containing diluent.

2. The composition of claim 1 wherein said stabilized silver nanoparticles comprise silver particles having a particle size in the range of about 5 up to about 200 nanometers and a capping agent.

3. The composition of claim 2 wherein said capping agent is polyvinyl alcohol, poly(N-vinyl-2-pyrrolidone), gum arabic, α-methacrylic acid, 11-mercaptoundecanoic acid or the disulfide derivative thereof, citric acid, trisodium citrate, stearic acid, palmitic acid, octanoic acid, decanoic acid, polyethylene glycol and derivatives thereof, polyacrylic acid and aminomodified polyacrylic acid, 2-mercaptoethanol, starch, or a mixture of any two or more thereof.

4. The composition of claim 2 wherein said capping agent comprises in the range of about 0.05 up to about 5 weight percent of the composition.

5. The composition of claim 1 wherein said silver particles comprise in the range of about 20 up to about 95 weight percent of the composition.

6. The composition of claim 1 wherein said acidic component is phosphoric acid, vinylphosphoric acid, polyphosphoric acid, formic acid, acetic acid, chloroacetic acid, trifluoroacetic acid, oxalic acid, oleic acid, benzoic acid, p-toluenesulfonic acid, or a mixture of any two or more thereof.

7. The composition of claim 1 wherein said acidic component comprises in the range of about 0.1 up to about 5 weight percent of the composition.

8. The composition of claim 1 wherein said thermoset resin is an epoxy-functionalized resin, an acrylate, a cyanate ester, a silicone, an oxetane, a maleimide, or a mixture of any two or more thereof.

9. The composition of claim 8 wherein said epoxy-functionalized resin is a liquid-type epoxy resin based on bisphenol A, a solid-type epoxy resin based on bisphenol A, a liquid-type epoxy resin based on bisphenol F, multifunctional epoxy resins based on phenol-novolac resin, dicyclopentadiene-type epoxy resin, naphthalene-type epoxy resin, or a mixture of any two or more thereof.

10. The composition of claim 9 wherein said epoxy-functionalized resin is the diepoxide of the cycloaliphatic alcohol, hydrogenated bisphenol A or a difunctional cycloaliphatic glycidyl ester of hexahydrophthallic anhydride.

11. The composition of claim 1 wherein said thermoset resin comprises in the range of about 0.1 up to about 5 weight percent of the composition.

12. The composition of claim 1 wherein said hydroxy-containing diluent is selected from the group consisting of water, methanol, ethanol, propanol, ethylene glycol, propylene glycol, glycerol, terpineol, and mixtures of any two or more thereof.

13. The composition of claim 1 wherein said hydroxy-containing diluent comprises in the range of about 5 up to about 80 weight percent of the composition.

14. A touch panel display comprising a transparent substrate having an electrically conductive layer thereon, wherein said electrically conductive layer comprises a cured layer of the composition of claim 1.

15. A method of preparing a conductive network, said method comprising:
applying a composition according to claim 1 to a suitable substrate, and thereafter
sintering said composition.

16. The method of claim 15 wherein said sintering is carried out at a temperature no greater than about 150° C.

17. The method of claim 16 wherein said sintering is carried out for a time in the range of 0.5 up to about 30 minutes.

18. The method of claim 15 wherein said sintering is carried out at a temperature no greater than about 120° C.

19. The method of claim 18 wherein said sintering is carried out for a time in the range of 0.1 up to about 2 hours.

20. The method of claim 15 wherein said substrate is polyethylene terephthalate, polymethyl methacrylate, polyethylene, polypropylene, polycarbonate, an epoxy resin, polyimide, polyamide, polyester, or glass.

21. A conductive network prepared by the method of claim 15.

22. A conductive network comprising a sintered array of nanoparticulate silver particles having a resistivity of no greater than 1×10⁻⁴ Ohms.cm.

23. The conductive network of claim 22 further comprising a substrate therefor, wherein the adhesion between said conductive network and said substrate is at least level 1B, as determined by ASTM standard cross-cut tape test pursuant to test method D 3359-97.

24. A method for adhering silver particles having a particle size in the range of about 5 up to about 200 nanometers to a non-metallic substrate, said method comprising:
applying a composition according to claim 1 to said substrate, and thereafter
sintering said composition.

25. The method of claim 24 wherein said substrate is polyethylene terephthalate, polymethyl methacrylate, polyethylene, polypropylene, polycarbonate, an epoxy resin, polyimide, polyamide, polyester, or glass.

26. A method for improving the adhesion of nanoparticulate thermoset resin to a non-metalic substrate, said method comprising including:
an acidic component, and
an hydroxy-containing diluent
in said silver-filled thermoset resin.
